(19) United States
(12) Patent Application Publication
(10) Pub. No.: US 2026/0206164 A1
(43) Pub. Date: Jul. 16, 2026

(54) ACCOMMODATION MODULE AND ELECTRONIC DEVICE INCLUDING THE SAME

(71) Applicant: LANNER ELECTRONICS INC., New Taipei City (TW)

(72) Inventor: YEN-YIN YU, Yilan City (TW)

(73) Assignee: LANNER ELECTRONICS INC., New Taipei City (TW)

(21) Appl. No.: 19/270,034

(22) Filed: Jul. 15, 2025

(30) Foreign Application Priority Data
Jan. 15, 2025 (TW) 114101624

(51) Int. Cl. H05K 7/14; H05K 7/02

(52) U.S. Cl. CPC H05K 7/142; H05K 7/023; H05K 7/1418; H05K 7/1429; H05K 7/1435

(57) ABSTRACT

The present invention discloses an accommodation module for being integrated in a housing case of an electronic device. In an application of high-level device, the accommodation module comprises a lower layer accommodation unit and an upper layer accommodation unit, in which the two units are all able to receive N numbers of removable electronic modules. On the other hand, in an application of low-level device, a total number of the upper layer accommodation unit's accommodation spaces can be changed (reduced), thereby limiting the upper layer accommodation unit capable of merely receiving R(R<N) numbers of removable electronic modules. Further, in other applications, the accommodation spaces of the upper layer accommodation unit can also be rearranged, such that the upper layer accommodation unit is able to receive at least one PCIE expansion card and/or at least one removable electronic module.

### CROSS-REFERENCE TO RELATED APPLICATIONS

This application claims priority to Taiwan Invention Patent Application No. 114101624, filed on Jan. 15, 2025, the entire disclosure of which is hereby incorporated by reference.

### TECHNICAL FIELD

The present invention relates to the technical field of electronic devices, particularly to an accommodation module integrated within a housing case to accommodate multiple electronic modules.

### BACKGROUND

It is known that computer systems, including network appliances, data centers, desktop computers, industrial computers, gaming consoles, etc., are inevitably equipped with at least one cooling device to assist in dissipating heat from internal heat sources (e.g., electronic chips or electronic modules). Taking network devices such as servers or network switches as an example, they are categorized into low-level, mid-level, and high-level devices, with different models paired with various network interface modules, such as Ethernet modules or SFP fiber optic network modules. Therefore, during the development phase of computer systems like network devices, mechanical engineers must design corresponding housing cases based on the device model. As the number of models increases, so does the number of housing cases that mechanical engineers need to develop, leading to higher R&D resource consumption for companies and increased workload for mechanical engineers.

In summary, there is a need to develop and design a housing case that can flexibly replace electronic modules according to the device model, making it suitable for various types of computer systems. In view of this, the inventors of the present invention have conducted extensive research and finally developed the accommodation module described herein.

### SUMMARY

The primary objective of the present invention is to provide an accommodation module for being integrated in a housing case of an electronic device. In an application of high-level device, the accommodation module comprises a lower layer accommodation unit and an upper layer accommodation unit, in which the two units are all able to receive N numbers of removable electronic modules. On the other hand, in an application of low-level device, a total number of the upper layer accommodation unit's accommodation spaces can be changed (reduced), thereby limiting the upper layer accommodation unit capable of merely receiving R(R<N) numbers of removable electronic modules. Further, in other applications, the accommodation spaces of the upper layer accommodation unit can also be rearranged, such that the upper layer accommodation unit is able to receive at least one PCIE expansion card and/or at least one removable electronic module.

In summary, the accommodation module of the present invention offers the following advantages:
(1) When applying the accommodation module of the present invention, engineers can share the housing case and the accommodation module across high-level, low-level, and special application device models.
(2) Sharing the housing case and the accommodation module of the present invention across multiple device models reduces R&D resource consumption for companies, alleviates the workload of mechanical engineers, and lowers production costs.
(3) Different device models can meet various application needs of customers.

To achieve the above objective, the present invention proposes an embodiment of the accommodation module for being integrated in a housing case of an electronic device. A side plate of the housing case is provided with at least one first opening, and the accommodation module comprises a first accommodation unit, which comprises:
N first partition plates arranged inside the housing case, each having a first side surface, a second side surface, a front edge, a base edge, a rear edge, and a top edge, wherein the first side surface and the base edge are connected to a first base-side connecting plate, and the first side surface and the top edge are connected to a first top-side connecting plate;
N second partition plates arranged inside the housing case, each also having a first side surface, a second side surface, a front edge, a base edge, a rear edge, and a top edge, wherein the first side surface and the base edge are connected to a second base-side connecting plate, and the first side surface and the top edge are connected to a second top-side connecting plate; and
a first plate member overlapping with the N first top-side connecting plates and the N second top-side connecting plates;
wherein among a 2^{nd} to a N^{th} first partition plates and a 1^{st} to a (N−1)^{th} second partition plates comprised in the first accommodation unit, the second side surface of the first partition plate and the second side surface of the second partition plate are in contact with each other;
wherein in the first accommodation unit, the N first partition plates, the N second

partition plates, and the first plate member collectively enclose to form N first accommodation spaces for accommodating N electronic modules, with an i^{th} first partition plate and an i^{th} second partition plate serving as two sidewalls of an i^{th} first accommodation space, where i is a positive integer ranging from 1 to N.

In an embodiment, in the i^{th} first accommodation space, the first side surface of the first

partition plate is provided with at least one first guide rail structure, and the first side surface of the second partition plate is provided with at least one second guide rail structure opposite to the at least one first guide rail structure.

In an embodiment, the first partition plate is provided with at least one first side threaded bore, and the second partition plate is provided with at least one second side threaded bore.

In an embodiment, among the 2^{nd} to the N^{th} first partition plates and the 1^{st} to the (N−1)^{t} second partition plates comprised in the first accommodation unit, the at least one first side threaded bore of the first partition plate corresponds to the at least one second side threaded bore of the second partition plate.

In an embodiment, a first front-side connecting plate is connected to the front side and the second side of the first partition plate, and a second front-side connecting plate is connected to the front side and the second side of the second partition plate.

In an embodiment, the first front-side connecting plate has a first front-side threaded bore, and the second front-side connecting plate has a second front-side threaded bore.

In an embodiment, the base side of the first partition plate is formed with at least one first notch, and the first base-side connecting plate is further connected with at least one first base-side extension plate correspondingly passing through the at least one first notch.

In an embodiment, the second base-side connecting plate is formed with at least one second notch, and in a case where the second side of the first partition plate and the second side of the second partition plate are in contact with each other, the at least one first base-side extension plate is located within the at least one second notch.

In an embodiment, the first base-side connecting plate has at least one first base-side threaded bore, the first base-side extension plate has M second base-side threaded bores, and the second base-side connecting plate has P third base-side threaded bores, where both M and P are positive integers.

In an embodiment, the at least one first base-side threaded bore of the first base-side connecting plate of the 1^{st} first partition plate corresponds to at least one first fixing threaded bore formed on a bottom of the housing case, and the P third base-side threaded bores of the second base-side connecting plate of a N^{th} second partition plate correspond to P second fixing threaded bores formed on the bottom of the housing case.

In an embodiment, the bottom of the housing case further comprises M×(N−1) third

fixing threaded bores, and among the 2^{nd} to the N^{th} first partition plates, the M second base-side threaded bores of each first base-side extension plate correspond to M of the third fixing threaded bores.

In an embodiment, the first top-side connecting plate has at least one first top-side threaded bore, and the second top-side connecting plate has at least one second top-side threaded bore and Q embedment members, where Q is a positive integer.

In an embodiment, the first plate member has a plurality of first structures, and the plurality of first structures comprise:
at least one first threaded bore corresponding to the at least one first top-side threaded bore of the first top-side connecting plate of the 1^{st} first partition plate;
at least one second threaded bore corresponding to the at least one second top-side threaded bore of the second top-side connecting plate of the N^{th} second partition plate;
Q×K cup-shaped members, where K is a positive integer, each cup-shaped member consisting of a base plate and an annular side plate, wherein the annular side plate is connected to a first surface of the first plate member, and an accommodation space of each cup-shaped member is a recess concave from a second surface of the first plate member;
Q×K first slotted holes respectively formed on the Q×K base plates and located within the accommodation space;
Q×K first guide slots respectively communicating with the Q×K first slotted holes;
at least one third threaded bore;
P fourth threaded bores; and
P×K fifth threaded bores;
wherein among the 1^{st} to the (N−1)^{th} second partition plates, the embedment members enter the corresponding first slotted holes via the corresponding first guide slots, thereby being embedded within the first slotted holes.

In an optional embodiment, the accommodation module further comprises a second accommodation unit stacked on the first accommodation unit, wherein the second accommodation unit comprises L first partition plates and L second partition plates, and further comprises a second plate member stacked on the L first partition plates and the L second partition plates, where L is a positive integer.

In an embodiment, in the second accommodation unit, the L first partition plates and the L second partition plates are arranged on the first plate member of the first accommodation unit, such that the L first partition plates, the L second partition plates, and the second plate member collectively enclose to form L second accommodation spaces.

In an embodiment, in the second accommodation unit, a j^{th} first partition plate (11) and a j^{th} second partition plate (12) serve as two sidewalls of a j^{th} second accommodation space, where j is a positive integer ranging from 1 to L.

In an embodiment, in the second accommodation unit, among the 2^{nd} to a L^{th} first partition plates and the 1^{st} to a (L−1)^{th} second partition plates comprised in the second accommodation unit, the second side surface of the first partition plate and the second side surface of the second partition plate are in contact with each other.

In an embodiment, in the second accommodation unit, the at least one first threaded bore of the first base-side connecting plate of the 1^{st} first partition plate corresponds to the at least one third threaded bore of the first plate member, and the P third base-side threaded bores of the second base-side connecting plate of a L^{th} second partition plate correspond to the P fourth threaded bores of the first plate member.

In an embodiment, among the 1^{st} to the (L−1)^{th} second partition plates of the second accommodation unit, the P third base-side threaded bores of each second base-side connecting plate correspond to P fifth threaded bores.

In an embodiment, the second plate member comprises a plurality of second structures, and the plurality of second structures comprise:
at least one sixth threaded bore, wherein in the second accommodation unit, the at least one first top-side threaded bore of the first top-side connecting plate of the first partition plate corresponds to the at least one sixth threaded bore;
at least one seventh threaded bore, wherein in the second accommodation unit, the at least one second top-side threaded bore of the second top-side connecting plate of the L^{th} second partition plate corresponds to the at least one seventh threaded bore;
Q×K second slotted holes; and
Q×K second guide slots respectively communicating with the Q×K second slotted holes;
wherein among the 1^{st} to the (L−1)^{th} second partition plates of the second accommodation unit, the embedment members enter the corresponding second slotted holes via the corresponding second guide slots, thereby being embedded within the second slotted holes.

Additionally, the present invention proposes an electronic device, comprising a housing case and at least one electronic chip and at least one electronic module accommodated therein, wherein the housing case accommodates the accommodation module according to the present invention as described above.

In an embodiment, the electronic device is selected from the group consisting of a server, network switch, gateway, embedded computer, single-board computer, industrial computer, desktop computer, All-in-one computer, vehicle-mounted computer, security monitoring host, gaming console, and game console.

### BRIEF DESCRIPTION OF DRAWINGS

FIG. 1 is a first perspective view of an electronic device comprising an accommodation module of the present invention;

FIG. 2 is a second perspective view of the electronic device comprising the accommodation module of the present invention;

FIG. 3A is a first perspective view of the accommodation module of the present invention;

FIG. 3B is a second perspective view of the accommodation module of the present invention;

FIG. 4A is an exploded perspective view of a lower layer accommodation unit shown in FIG. 3A;

FIG. 4B is an exploded perspective view of the lower layer accommodation unit shown in FIG. 3B;

FIG. 5A is a first perspective view of a first partition plate and a second partition plate;

FIG. 5B is a second perspective view of the first partition plate and the second partition plate;

FIG. 6A is an exploded perspective view of an upper layer accommodation unit shown in FIG. 3A;

FIG. 6B is an exploded perspective view of the upper layer accommodation unit shown in FIG. 3B;

FIG. 7 is a third perspective view of an electronic device comprising the accommodation module of the present invention;

FIG. 8 is a fourth perspective view of an electronic device comprising the accommodation module of the present invention;

FIG. 9 is a fifth perspective view of an electronic device comprising the accommodation module of the present invention; and

FIG. 10 is a sixth perspective view of an electronic device comprising the accommodation module of the present invention.

### DESCRIPTION OF EMBODIMENTS

To enable the esteemed reviewing committee to further understand the structure, features, objectives, and advantages of the present invention, detailed descriptions with accompanying drawings and preferred embodiments are provided below.

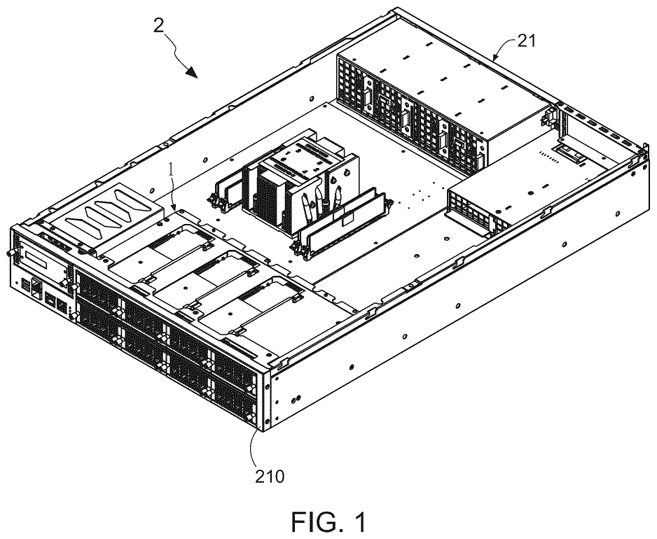

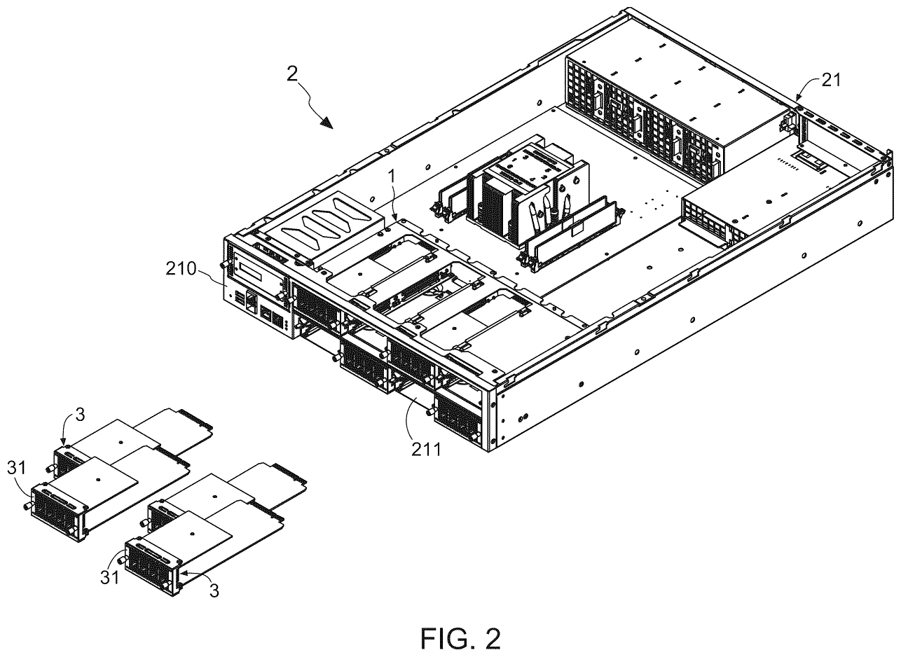

Please refer to FIGS. 1 and 2, which are the first and second perspective views, respectively, of an electronic device containing an accommodation module according to the present invention. As shown in FIGS. 1 and 2, the accommodation module 1 of the present invention is integrated in a housing case 21 of the electronic device 2. At least one first opening 211 is provided on a side plate 210 of the housing case 21. Notably, in applications for high-level devices, the accommodation module 1 of the present invention includes a lower layer accommodation unit and an upper layer accommodation unit, both of which can accommodate N removable electronic modules 3, such as Ethernet modules, SFP fiber network modules, PCIE expansion card modules, etc. Additionally, in feasible embodiments, the electronic device 2 may be, but is not limited to, a server, network switch, gateway, embedded computer, single-board computer, industrial computer, desktop computer, All-in-one computer, vehicle-mounted computer, security monitoring host, gaming host, or game console.

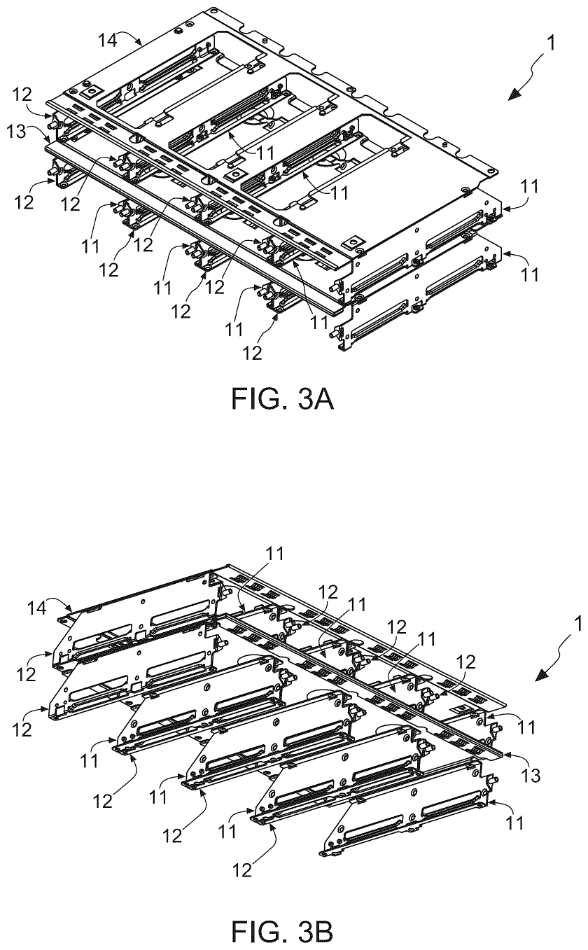

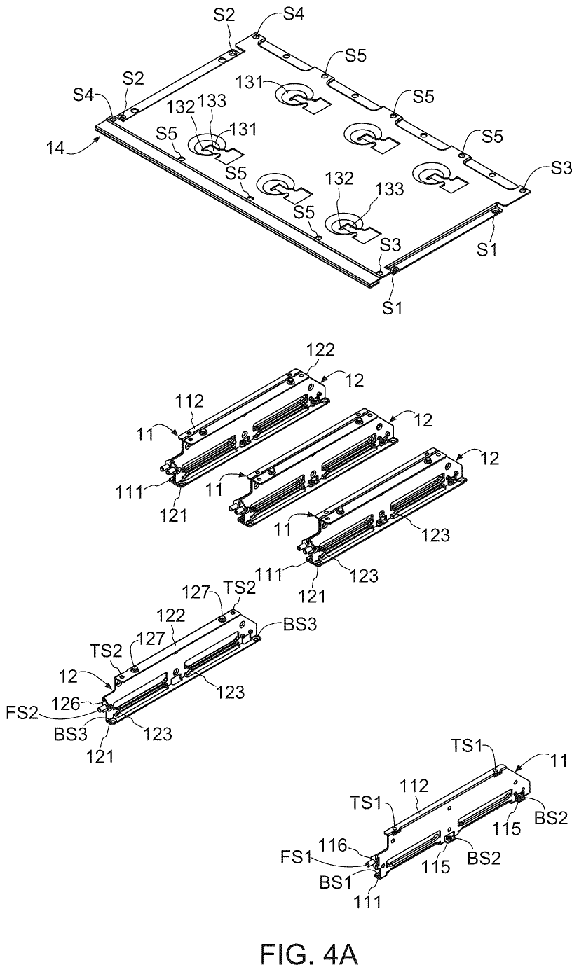

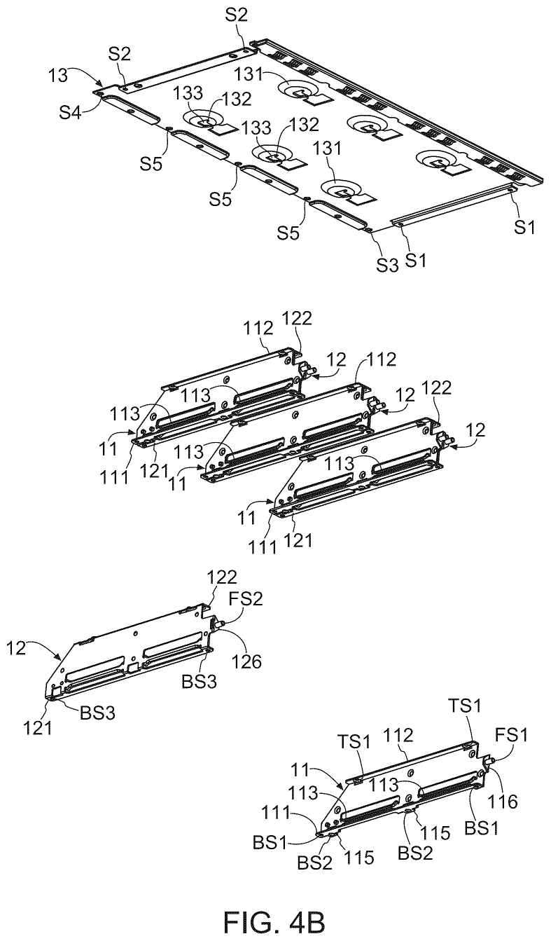

FIGS. 3A and 3B are the first and second perspective views of the accommodation module of the present invention. As shown in 3A and 3B, in the accommodation module 1 of the present invention, the lower layer accommodation unit includes: N first partition plates 11, N second partition plates 12, and a first plate member 13. Specifically, each of the first partition plates 11 is arranged inside the housing case 21 and has a first side surface, a second side surface, a front edge, a base-side edge, a rear edge, and a top-side edge. Relative to the first partition plate 11, each of the second partition plates 12 is arranged inside the housing case 21 and similarly has a first side surface, a second side surface, a front edge, a base-side edge, a rear edge, and a top-side edge. Moreover, the first plate member 13 is stacked on top of the N first partition plates 11 and the N second partition plates 12. Furthermore, FIG. 4A is an exploded perspective view of the lower layer

accommodation unit shown in FIG. 3A, and FIG. 4B is an exploded perspective view of the lower layer accommodation unit shown in FIG. 3B. As illustrated in FIGS. 3A, 3B, 4A, and 4B, the first side surface and the base-side edge of the first partition plate 11 are connected to a first base-side connecting plate 111, and the first side surface and the top-side edge are connected to a first top-side connecting plate 112. Additionally, the first side surface and the base-side edge of the second partition plate 12 are connected to a second base-side connecting plate 121, and the first side surface and the top-side edge are connected to a second top-side connecting plate 122.

According to the design of the present invention, among the 2^{nd} to N^{th} first partition plates 11 and the 1^{st} to (N−1)^{th} second partition plates 12 included in the lower layer accommodation unit, the second side surface of the i^{th} first partition plate 11 and the second side surface of the (i+1)^{th} second partition plate 12 are in contact with each other. Moreover, in the lower layer accommodation unit, the N first partition plates 11, the N second partition plates 12, and the first plate member 13 collectively enclose to form N first accommodation spaces for accommodating N electronic modules, with the i^{th} first partition plate 11 and the i^{th} second partition plate 12 serving as the two sidewalls of the i^{th} first accommodation space. Specifically, N is a positive integer, i is a positive integer ranging from 1 to N.

Taking N=4 as an example, among the 2^{nd} to 4^{th} first partition plates 11 and the 1^{st} to (N=3)^{th} second partition plates 12 included in this lower layer accommodation unit, the second side surface of the first partition plate 11 and the second side surface of the second partition plate 12 are in contact with each other. Moreover, among the N first accommodation spaces included in this lower layer accommodation unit, the i=1^{st}, 2^{nd}, 3^{rd}, or 4^{th} first partition plate 11 and the i=1^{st}, 2^{nd}, 3^{rd}, or 4^{th} second partition plate 12 serve as the two sidewalls of the i=1^{st}, 2^{nd}, 3^{rd}, or 4^{th} first accommodation space.

To reiterate, among the 2^{nd} to the N^{th} first partition plates 11 and the 1^{st} to the (N−1)^{th} second partition plates 12, the second side surface of the i^{th} first partition plate 11 and the second side surface of the (i+1)^{th} second partition plate 12 are in contact with each other. Furthermore, at least one first side threaded bore SS1 is provided on the first partition plate 11, and at least one second side threaded bore SS2 is provided on the second partition plate 12. Understandably, for the 2^{nd} to the N^{th} first partition plates 11 and the first to the (N−1)^{th} second partition plates 12 included in this lower layer accommodation unit, by screwing bolts into the first side threaded bore SS1 and the second side threaded bore SS2, the i^{th} first partition plate 11 and the (i+1)^{th} second partition plate 12 are tightly attached to each other.

Additionally, the base-side edge of the first partition plate 11 is formed with at least one first notch 114, and the first base-side connecting plate 111 is further connected with at least one first base-side extension plate 115, which correspondingly passes through the at least one first notch 114. Moreover, the second base-side connecting plate 121 is formed with at least one second notch 124, and when the second side surface of the first partition plate 11 and the second side surface of the second partition plate 12 are in contact with each other, the at least one first base-side extension plate 115 is positioned within the at least one second notch 124.

Moreover, to facilitate the insertion of each removable electronic module 3 into the first accommodation space, at least one first guide rail structure 113 is formed on the first side of the first partition plate 11 within each first accommodation space, and at least one second guide rail structure 123 is formed on the first side of the second partition plate 12, opposite to the at least one first guide rail structure 113. Additionally, a first front-side connecting plate 116 is connected to the front edge and the second side of the first partition plate 11, and the first front-side connecting plate 116 has a first front-side threaded bore FS1. In contrast to the first partition plate 11, a second front-side connecting plate 126 is connected to the front edge and the second side of the second partition plate 12, and the second front-side connecting plate 126 has a second front-side threaded bore FS2. With this design, after a removable electronic module 3 is placed in a first accommodation space, two screws on a panel 31 of the removable electronic module 3 can be correspondingly threaded into the first front-side threaded bore FS1 and the second front-side threaded bore FS2, thereby securing the removable electronic module 3.

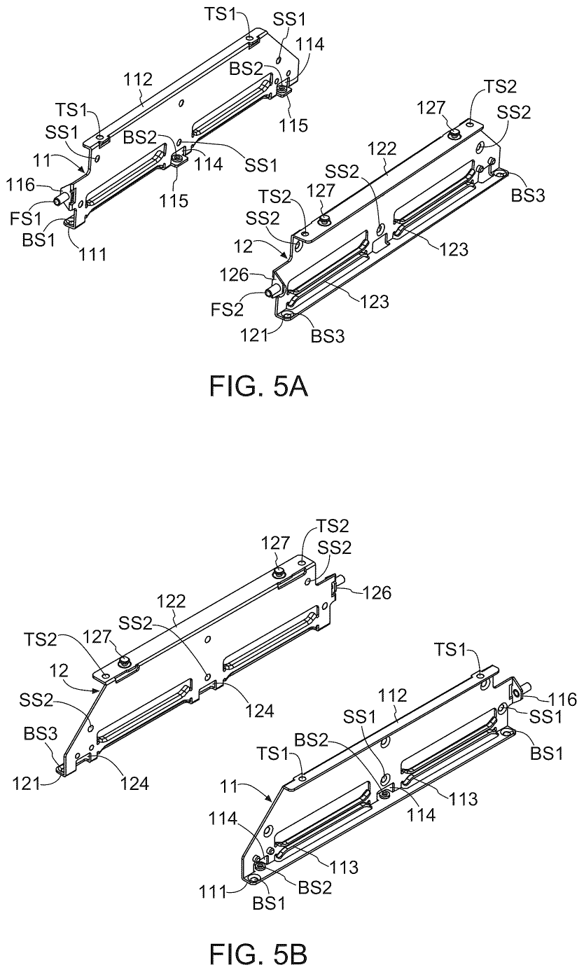

FIGS. 5A and 5B show the first and second perspective views of a first partition plate 11 and a second partition plate 12. As illustrated in FIGS. 4A, 4B, 5A, and 5B, the first base-side connecting plate 111 of the first partition plate 11 has at least one first base-side threaded bore BS1, and the first base-side extension plate 115 has M second base-side threaded bores BS2. On the other hand, the second base-side connecting plate 121 of the second partition plate 12 has P third base-side threaded bores BS3, where M and P are both positive integers. Furthermore, in the lower layer accommodation unit, the at least one first base-side threaded bore BS1 of the first base-side connecting plate 111 of the 1^{st} first partition plate 11 corresponds to at least one first fixing threaded bore formed on the bottom of the housing case 21, and the P third base-side threaded bores BS3 of the second base-side connecting plate 121 of the N^{th} second partition plate 12 correspond to P second fixing threaded bores formed on the bottom of the housing case 21. In more detail, M×(N−1) third fixing threaded bores are also formed on the bottom of the housing case 21. Moreover, among the 2^{nd} to the N^{th} first partition plates 11, the M second base-side threaded bores BS2 of the first base-side extension plate 115 correspond to M of the third fixing threaded bores.

Furthermore, the first plate member 13 has a plurality of first structures, which include: at least one first threaded bore S1, at least one second threaded bore S2, Q×K cup-shaped members 131, Q×K first slotted holes 132, and Q×K first guide slots 133. In one embodiment, each of the first top-side connecting plates 112 has at least one first top-side threaded bore TS1, and each of the second top-side connecting plates 122 has at least one second top-side threaded bore TS2 and Q embedment members 127, where Q is a positive integer. As shown in FIGS. 4A, 4B, 5A, and 5B, the at least one first threaded bore S1 corresponds to the at least one first top-side threaded bore TS1 of the first top-side connecting plate 112 of the 1^{st} first partition plate 11, and the at least one second threaded bore S2 corresponds to the at least one second top-side threaded bore TS2 of the second top-side connecting plate 122 of the N^{th} second partition plate 12.

On the other hand, according to the present invention, K is a positive integer. For example, in the case of K=4, N (i.e., the number of first partition plates 11 and second partition plates 12) can be 1, 2, 3, or 4.

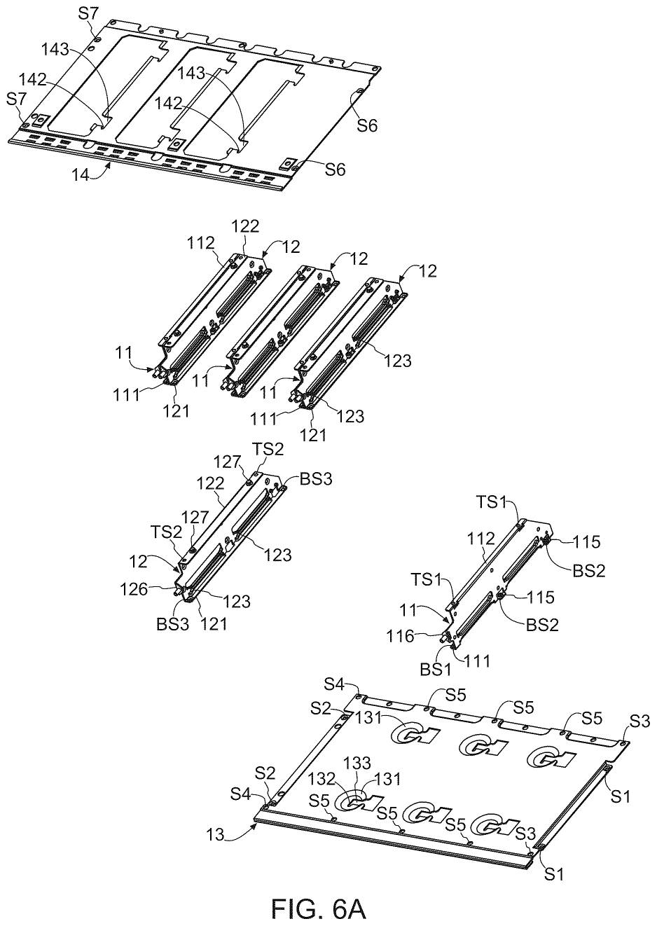

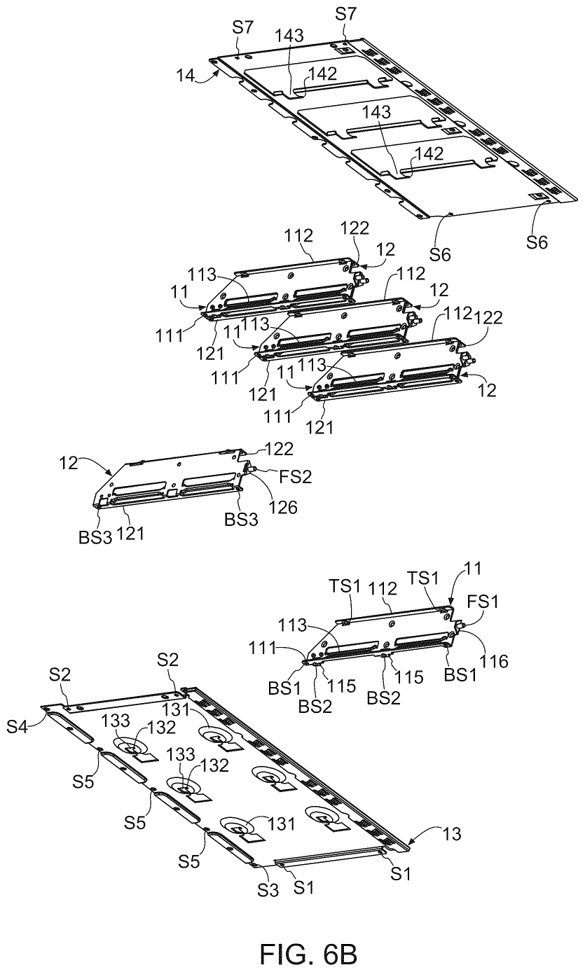

In one embodiment, each of the cup-shaped members 131 consists of a base plate and an annular side plate, with the annular side plate connected to a first surface of the first plate member 13, and an accommodation space of each cup-shaped member 131 is a recess formed by indenting from a second surface of the first plate member 13. Moreover, the Q×K first slotted holes 132 are respectively formed on the Q×K base plates, and the Q×K first guide slots 133 respectively communicate with the Q×K first slotted holes 132, wherein each first slotted hole 132 is located within the accommodation space. It is particularly noted that, among the 1^{st} to (N−1)^{th} second partition plates 12, the embedment members 127 enter the corresponding first slotted holes 132 via the corresponding first guide slots 133, thereby being embedded within the first slotted holes 132. FIG. 6A is an exploded perspective view of the upper layer accommodation unit shown in FIG. 3A, and FIG. 6B is an exploded perspective view of the upper layer accommodation unit shown in FIG. 3B. According to the design of the present invention, the upper layer accommodation unit is stacked on top of the lower layer accommodation unit and includes L of the first partition plates 11 and L of the second partition plates 12, and further include a second plate member 14 stacked on top of the L first partition plates 11 and the L second partition plates 12. It should be understood that L represents the quantity of the first partition plates 11 and the second partition plates 12 included in the upper layer accommodation unit, which may therefore be 1, 2, 3, or 4. Thus, within the upper layer accommodation unit, the L first partition plates 11 and the L second partition plates 12 are arranged on the first plate member 13 of the lower layer accommodation unit, so that the L first partition plates 11, the L second partition plates 12, and the second plate member 14 collectively enclose to form L second accommodation spaces. Moreover, the j^{th} first partition plate 11 and the j^{th} second partition plate 12 serve as the two sidewalls of the j^{th} second accommodation space, where j is a positive integer ranging from 1 to L. Notably, among the 2^{nd} to L-th first partition plates 11 and the 1^{st} to (L−1)^{th} second partition plates 12 included in the upper layer accommodation unit, the second side surface of the j^{th} first partition plate 11 and the second side surface of the (j+1)^{th} second partition plate 12 are in contact with each other.

To supplement, the plurality of first structures of the first plate member 13 further include at least one third threaded bore S3, P fourth threaded bores S4, and P×K fifth threaded bores S5. Additionally, within the upper layer accommodation unit, the at least one first base-side threaded bore BS1 of the first base-side connecting plate 111 of the 1^{st} first partition plate 11 corresponds to the at least one third threaded bore S3 of the first plate member 13, and the P third base-side threaded bores BS3 of the second base-side connecting plate 121 of the L^{th} second partition plate 12 correspond to the P fourth threaded bores S4 of the first plate member 13. Furthermore, among the 1^{st} to (L−1)^{th} second partition plates 12 of the upper layer accommodation unit, the P third base-side threaded bores BS3 of each second base-side connecting plate 121 correspond to P of the fifth threaded bores S5.

In one embodiment, the second plate member 14 has a plurality of second structures, and the plurality of second structures include: at least one sixth threaded bore S6, at least one seventh threaded bore S7, Q×K second slotted holes 142, and Q×K second guide slots 143. In the upper layer accommodation unit, the at least one first top-side threaded bore TS1 of the first top-side connecting plate 112 of the 1^{st} first partition plate 11 corresponds to the at least one sixth threaded bore S6, and the at least one second top-side threaded bore TS2 of the second top-side connecting plate 122 of the L^{th} second partition plate 12 corresponds to the at least one seventh threaded bore S7. In more detail, the Q×K second guide slots 143 are respectively connected to the Q×K second slotted holes 142. With this design, among the 1^{st} to (L−1)^{th} second partition plates 12 of the upper layer accommodation unit, the embedment memberS 127 enter the corresponding second slotted holes 142 through the corresponding second guide slots 143, thereby being embedded within the second slotted holes 142.

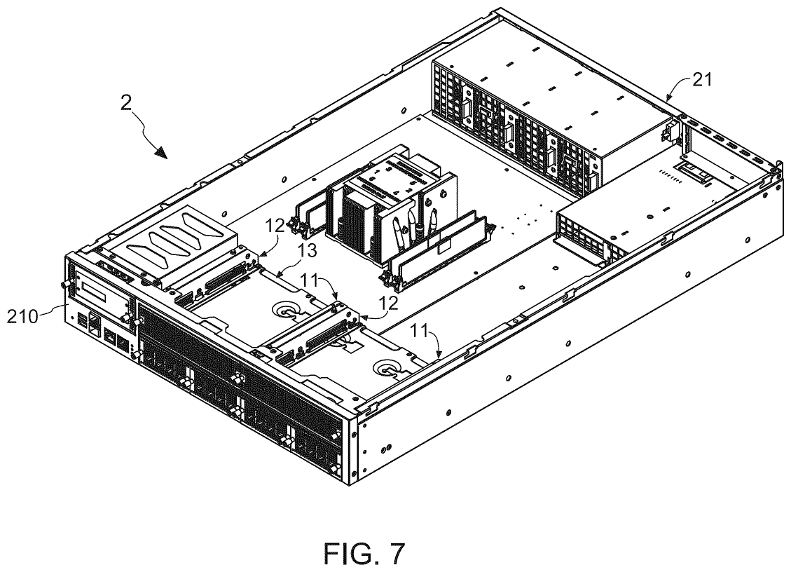

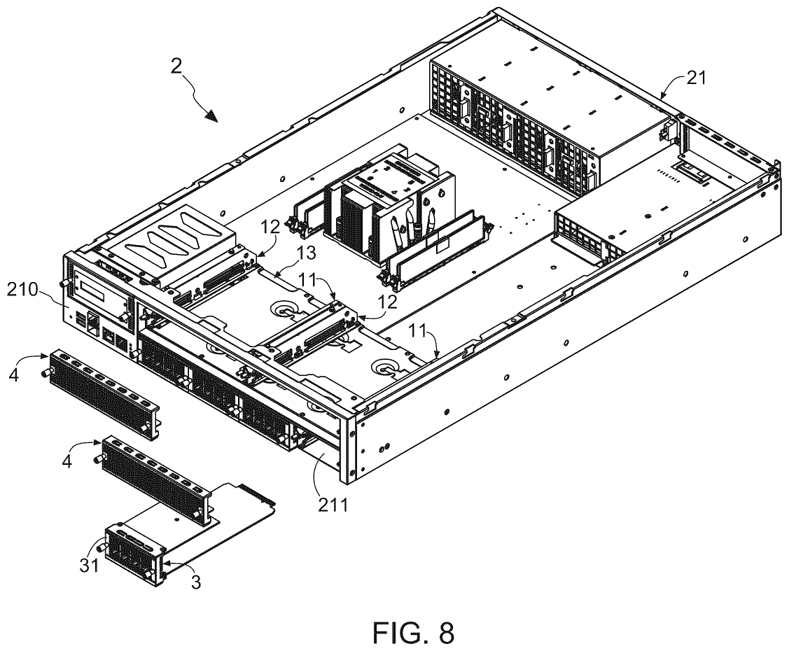

Furthermore, FIGS. 7 and 8 are the third and fourth perspective views, respectively, of an electronic device incorporating the accommodation module of the present invention. As shown in FIGS. 3A, 3B, 4A, 4B, 6A, 6B, 7, and 8, in applications for low-level devices, the accommodation space of the upper layer accommodation unit can be modified (reduced) so that the upper layer accommodation unit can only accommodate R(<N) removable electronic modules 3 or no electronic modules at all. Specifically, in FIGS. 7 and 8, the first partition plates 11 and second partition plates 12 included in the upper layer accommodation unit are reduced to two, and two panel modules 14 are coupled to the two first front-side threaded bores FS1 of the two first partition plates 11 and the two second front-side threaded bores FS2 of the two second partition plates 12. At the same time, it should be understood that the second plate member 14 of the upper layer accommodation unit is not shown in FIGS. 7 and 8, the purpose of which is to clearly display the two first partition plates 11 and the two second partition plates 12.

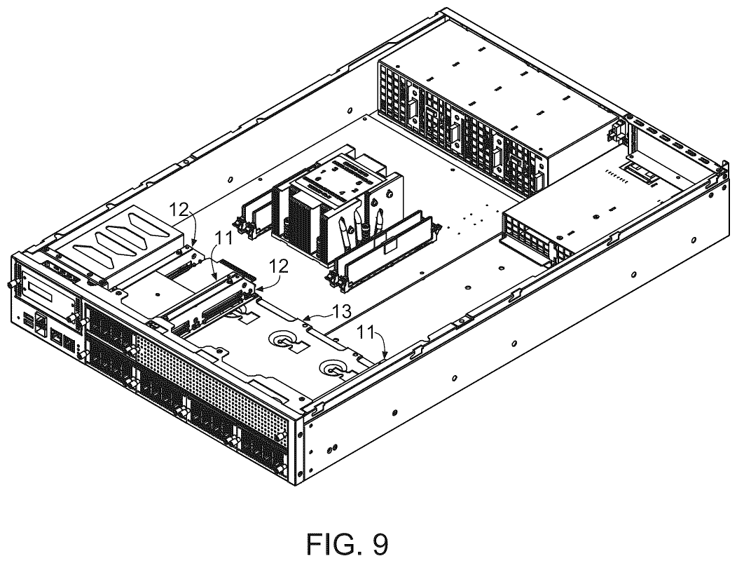

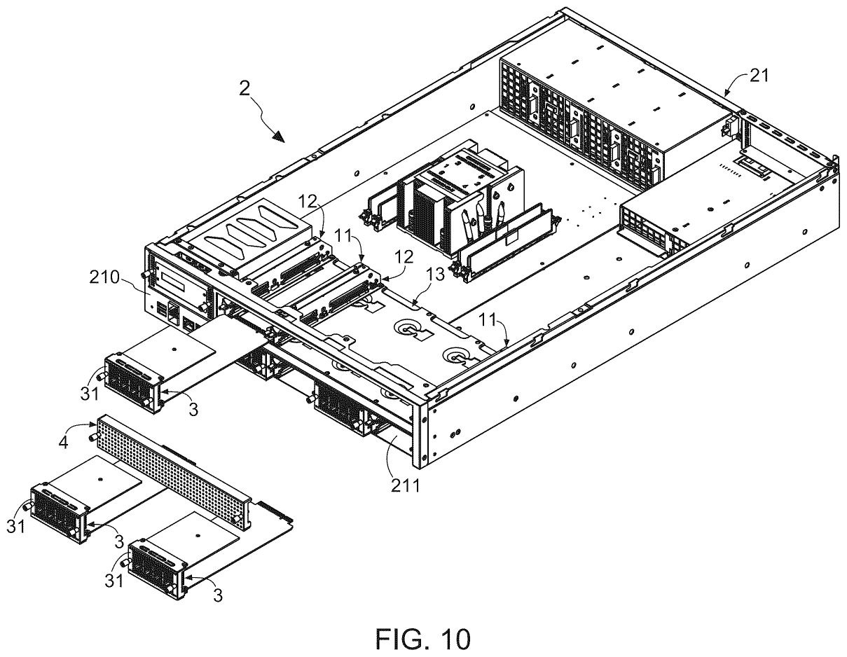

On the other hand, FIGS. 9 and 10 are the fifth and sixth perspective views of the electronic device containing the accommodation module of the present invention, respectively. As shown in FIGS. 3A, 3B, 4A, 4B, 6A, 6B, 9, and 10, in other applications, the accommodation space of the upper layer accommodation unit can also be modified, allowing the upper layer accommodation unit to accommodate at least one PCIE expansion card and/or at least one removable electronic module 3. Specifically, in FIGS. 9 and 10, the first partition plate 11 and the second partition plate 12 included in the upper layer accommodation unit are reduced to two, and a panel module 14 is coupled to the first front-side threaded bore FS1 of a first partition plate 11 and the second front-side threaded bore FS2 of a second partition plate 12. Meanwhile, a removable electronic module 3 is placed in a second accommodation space of the upper layer accommodation unit.

In summary, the accommodation module 1 of the present invention has been fully and clearly described. Moreover, the accommodation module 1 of the present invention offers the following advantages:
(1) When applying the accommodation module 1 of the present invention, engineers designing high-level, low-level, and special application devices can share the housing case and the accommodation module of the present invention.
(2) With multiple device models sharing the housing case and the accommodation module of the present invention, the company's R&D resource consumption is reduced, the workload of mechanical engineers is alleviated, and production costs are lowered.
(3) Different device models can meet various application needs of customers.
(4) In applications for high-level devices, the accommodation module 1 of the present invention includes a lower layer accommodation unit and an upper layer accommodation unit, both of which can accommodate N removable electronic modules.
(5) In applications for low-level devices, the accommodation space of the upper layer accommodation unit can be modified (reduced), allowing the upper layer accommodation unit to accommodate only R (R<N) removable electronic modules or no electronic modules at all.
(6) In other applications, the accommodation space of the upper layer accommodation unit can also be modified, allowing it to accommodate at least one PCIE expansion card and/or at least one removable electronic module.

However, it must be emphasized that the foregoing invention represents the preferred embodiments of the present invention. Any partial changes or modifications derived from the technical concept of the present invention and easily conceivable by those skilled in the art shall remain within the patent scope of the present invention.

What is claimed is:

1. An accommodation module for being integrated in a housing case of an electronic device, wherein a side plate of the housing case is provided with at least one first opening, and the accommodation module comprises a first accommodation unit, which comprises:
N first partition plates arranged inside the housing case, each having a first side surface, a second side surface, a front edge, a base edge, a rear edge, and a top edge, wherein the first side surface and the base edge are connected to a first base-side connecting plate, and the first side surface and the top edge are connected to a first top-side connecting plate;
N second partition plates arranged inside the housing case, each also having a first side surface, a second side surface, a front edge, a base edge, a rear edge, and a top edge, wherein the first side surface and the base edge are connected to a second base-side connecting plate, and the first side surface and the top edge are connected to a second top-side connecting plate; and
a first plate member overlapping with the N first top-side connecting plates and the N second top-side connecting plates;
wherein among a 2^{nd} to a N^{th} first partition plates and a 1^{st} to a (N−1)^{th} second partition plates comprised in the first accommodation unit, the second side surface of the first partition plate and the second side surface of the second partition plate are in contact with each other;
wherein in the first accommodation unit, the N first partition plates, the N second partition plates, and the first plate member collectively enclose to form N first accommodation spaces for accommodating N electronic modules, with an i^{th} first partition plate and an i^{th} second partition plate serving as two sidewalls of an i^{th} first accommodation space, where i is a positive integer ranging from 1 to N.

2. The accommodation module according to claim 1, wherein in the i^{th} first accommodation space, the first side surface of the first partition plate is provided with at least one first guide rail structure, and the first side surface of the second partition plate is provided with at least one second guide rail structure opposite to the at least one first guide rail structure.

3. The accommodation module according to claim 1, wherein the first partition plate is provided with at least one first side threaded bore, and the second partition plate is provided with at least one second side threaded bore.

4. The accommodation module according to claim 3, wherein among the 2^{nd} to the N^{th} first partition plates and the 1^{st} to the (N−1)^{th} second partition plates comprised in the first accommodation unit, the at least one first side threaded bore of the first partition plate corresponds to the at least one second side threaded bore of the second partition plate.

5. The accommodation module according to claim 1, wherein a first front-side connecting plate is connected to the front side and the second side of the first partition plate, and a second front-side connecting plate is connected to the front side and the second side of the second partition plate.

6. The accommodation module according to claim 5, wherein the first front-side connecting plate has a first front-side threaded bore, and the second front-side connecting plate has a second front-side threaded bore.

7. The accommodation module according to claim 1, wherein the base side of the first partition plate is formed with at least one first notch, and the first base-side connecting plate is further connected with at least one first base-side extension plate correspondingly passing through the at least one first notch.

8. The accommodation module according to claim 7, wherein the second base-side connecting plate is formed with at least one second notch, and in a case where the second side of the first partition plate and the second side of the second partition plate are in contact with each other, the at least one first base-side extension plate is located within the at least one second notch.

9. The accommodation module according to claim 7, wherein the first base-side connecting plate has at least one first base-side threaded bore, the first base-side extension plate has M second base-side threaded bores, and the second base-side connecting plate has P third base-side threaded bores, where both M and P are positive integers.

10. The accommodation module according to claim 9, wherein the at least one first base-side threaded bore of the first base-side connecting plate of the 1^{st} first partition plate corresponds to at least one first fixing threaded bore formed on a bottom of the housing case, and the P third base-side threaded bores of the second base-side connecting plate of a N^{th} second partition plate correspond to P second fixing threaded bores formed on the bottom of the housing case.

11. The accommodation module according to claim 10, wherein the bottom of the housing case further comprises M×(N−1) third fixing threaded bores, and among the 2^{nd} to the N^{th} first partition plates, the M second base-side threaded bores of each first base-side extension plate correspond to M of the third fixing threaded bores.

12. The accommodation module according to claim 11, wherein the first top-side connecting plate has at least one first top-side threaded bore, and the second top-side connecting plate has at least one second top-side threaded bore and Q embedment members, where Q is a positive integer.

13. The accommodation module according to claim 12, wherein the first plate member has a plurality of first structures, and the plurality of first structures comprise:
at least one first threaded bore corresponding to the at least one first top-side threaded bore of the first top-side connecting plate of the 1^{st} first partition plate;
at least one second threaded bore corresponding to the at least one second top-side threaded bore of the second top-side connecting plate of the N^{th} second partition plate;
Q×K cup-shaped members, where K is a positive integer, each cup-shaped member consisting of a base plate and an annular side plate, wherein the annular side plate is connected to a first surface of the first plate member, and an accommodation space of each cup-shaped member is a recess concave from a second surface of the first plate member;
Q×K first slotted holes respectively formed on the Q×K base plates and located within the accommodation space;
Q×K first guide slots respectively communicating with the Q×K first slotted holes;
at least one third threaded bore;
P fourth threaded bores; and
P×K fifth threaded bores;
wherein among the 1^{st} to the (N−1)^{th} second partition plates, the embedment members enter the corresponding first slotted holes via the corresponding first guide slots, thereby being embedded within the first slotted holes.

14. The accommodation module according to claim 13, further comprising a second accommodation unit stacked on the first accommodation unit, wherein the second accommodation unit comprises L first partition plates and L second partition plates, and further comprises a second plate member stacked on the L first partition plates and the L second partition plates, where L is a positive integer.

15. The accommodation module according to claim 14, wherein in the second accommodation unit, the L first partition plates and the L second partition plates are arranged on the first plate member of the first accommodation unit, such that the L first partition plates, the L second partition plates, and the second plate member collectively enclose to form L second accommodation spaces.

16. The accommodation module according to claim 15, wherein in the second accommodation unit, a j^{th} first partition plate (11) and a j^{th} second partition plate (12) serve as two sidewalls of a j^{th} second accommodation space, where j is a positive integer ranging from 1 to L.

17. The accommodation module according to claim 15, wherein in the second accommodation unit, among the 2^{nd} to a L^{th} first partition plates and the 1^{st} to a (L−1)^{th} second partition plates comprised in the second accommodation unit, the second side surface of the first partition plate and the second side surface of the second partition plate are in contact with each other.

18. The accommodation module according to claim 17, wherein in the second accommodation unit, the at least one first threaded bore of the first base-side connecting plate of the 1^{st} first partition plate corresponds to the at least one third threaded bore of the first plate member, and the P third base-side threaded bores of the second base-side connecting plate of a L^{th} second partition plate correspond to the P fourth threaded bores of the first plate member.

19. The accommodation module according to claim 18, wherein among the 1^{st} to the (L−1)^{th} second partition plates of the second accommodation unit, the P third base-side threaded bores of each second base-side connecting plate correspond to P fifth threaded bores.

20. The accommodation module according to claim 19, wherein the second plate member comprises a plurality of second structures, and the plurality of second structures comprise:
at least one sixth threaded bore, wherein in the second accommodation unit, the at least one first top-side threaded bore of the first top-side connecting plate of the first partition plate corresponds to the at least one sixth threaded bore;
at least one seventh threaded bore, wherein in the second accommodation unit, the at least one second top-side threaded bore of the second top-side connecting plate of the L^{th} second partition plate corresponds to the at least one seventh threaded bore;
Q×K second slotted holes; and
Q×K second guide slots respectively communicating with the Q×K second slotted holes;
wherein among the 1^{st} to the (L−1)^{th} second partition plates of the second accommodation unit, the embedment members enter the corresponding second slotted holes via the corresponding second guide slots, thereby being embedded within the second slotted holes.

21. An electronic device, comprising a housing case and at least one electronic chip and at least one electronic module accommodated therein, wherein the housing case accommodates the accommodation module according to claim 1.
